(19) United States
(12) Patent Application Publication
(10) Pub. No.: US 2008/0099841 A1
(43) Pub. Date: May 1, 2008

(54) METHOD AND STRUCTURE FOR REDUCING SOI DEVICE FLOATING BODY EFFECTS WITHOUT JUNCTION LEAKAGE

(75) Inventors: Xiangdong Chen, Poughquag, NY (US); Haining Yang, Wappingers Falls, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/554,621

(22) Filed: Oct. 31, 2006

(51) Int. Cl. H01L 27/12

(52) U.S. Cl. 257/347

(57) ABSTRACT

A method of reducing silicon-on-insulator (SOI) floating body effects in a semiconductor device includes forming a buried insulator layer over a substrate material; forming a crystalline SOI layer over the buried insulator layer; forming a gate conductor over the SOI layer; and performing an angled implant of the semiconductor device so as to introduce an amorphizing species into the SOI layer in an asymmetric manner with respect to source and drain regions of the device. The amorphizing species introduced into the source region of the device bridges across a source-to-body diode barrier, while the amorphizing species introduced into the drain region of the device are localized entirely therein.

### BACKGROUND

The present invention relates generally to semiconductor device processing techniques and, more particularly, to a method and structure for reducing silicon-on-insulator (SOD floating body effects without junction leakage.

Demands for increased performance, functionality and manufacturing economy for integrated circuits have resulted in extreme integration density in order to reduce signal propagation time and increase noise immunity, while also increasing the number of circuits and devices that can be formed on a chip or wafer by a single sequence of processes. Scaling of devices to such small sizes has also restricted operating margins and has necessitated an increased uniformity of electrical characteristics of semiconductor devices formed on a chip.

To satisfy this latter criterion, silicon-on-insulator (SOI) wafers have been used to exploit the improved quality of monocrystalline silicon through an active layer thereof formed on an insulator over a bulk silicon “handling” substrate. Similar attributes may be developed in similar structures of other types of semiconductor materials and alloys thereof. The improved quality of the semiconductor material of the active SOI layer allows transistors and other devices to be scaled to extremely small sizes with good uniformity of electrical properties.

Unfortunately, the existence of the insulator layer (also referred to a buried oxide layer, or BOX) which supports the development of the improved quality of semiconductor material also presents a problem known in the art as the “floating body effect” in transistor structures. The floating body effect is specific to transistors formed on substrates having an insulator layer. In particular, the neutral floating body is electrically isolated by source/drain and halo extension regions that form oppositely poled diode junctions at the ends of the transistor conduction channel and floating body, while the gate electrode is insulated from the conduction channel through a dielectric. The insulator layer in the substrate completes insulation of the conduction channel and thus prevents discharge of any charge that may develop in the floating body. Charge injection into the neutral body when the transistor is not conducting develops voltages in the conduction channel in accordance with the source and drain diode characteristics.

The floating body effect is induced by the excess carriers generated by hot electrons near the strongly filed gradient drain region, resulting in the enhancement in the body potential in SOI devices. It induces a threshold voltage reduction, resulting in a kink in output characteristics. The voltage developed due to charge collection in the transistor conduction channel has the effect of altering the switching threshold of the transistor. This effect, in turn, alters the signal timing and signal propagation speed, since any transistor will have a finite slew rate and the rise and fall time of signals is not instantaneous even when gate capacitance is very small. SOI switching circuits, in particular, suffer from severe dynamic floating body effects such as hysteresis and history effects. The onset of the kink effect in SOI switching circuits strongly depends on operating frequency, and produces Lorentzian-like noise overshoot and harmonic distortion.

In order to limit the charge that builds up in the floating body, a body contact may be incorporated into the device. However, this approach adversely affects the density of the device. Alternatively, the diode characteristics of the source and drain may be tailored. For example, floating body charge may be reduced by decreasing the potential barrier between source/drain and body junctions, such as by creating implant defects at the p/n junctions, which is a frequency independent approach. Unfortunately, as opposed to source diode leakage in a switching device, drain diode leakage increases the thermal power dissipated by a circuit, and reduces actual switching current resulting in lower speed.

Accordingly, it would be desirable to be able to reduce SOI floating body effects in a manner that does not result in increased drain leakage current, increased thermal power or speed reduction of the circuit.

### SUMMARY

The foregoing discussed drawbacks and deficiencies of the prior art are overcome or alleviated by a method of reducing silicon-on-insulator (SOI) floating body effects in a semiconductor device. In an exemplary embodiment, the method includes forming a buried insulator layer over a substrate material; forming a crystalline SOI layer over the buried insulator layer; forming a gate conductor over the SOI layer; and performing an angled implant of the semiconductor device so as to introduce an amorphizing species into the SOI layer in an asymmetric manner with respect to source and drain regions of the device. The amorphizing species introduced into the source region of the device bridges across a source-to-body diode barrier, while the amorphizing species introduced into the drain region of the device are localized entirely therein.

In another embodiment, a silicon-on-insulator (SOI) transistor device includes a buried insulator layer formed over a substrate material; a crystalline SOI layer over the buried insulator layer; forming a gate conductor over the SOI layer; and an amorphizing species distributed within the SOI layer in an asymmetric manner with respect to source and drain regions of the device; wherein the amorphizing species introduced into the source region of the device bridges across a source-to-body diode barrier, and wherein the amorphizing species distributed within the drain region of the device are localized entirely therein.

### TECHNICAL EFFECTS

As a result of the summarized invention, a solution is technically achieved in which a heavy species, such as Xe or Sb, is implanted into the source of a transistor to reduce an effective source diode barrier height. The heavy species are also prevented from being implanted into the drain diode junction interface, and without the use of an extra lithographic masking step. Thereby, cumulated body carriers may be discharged through the rail-connected source terminal without increasing drain leakage current, increasing thermal power or speed reduction of the circuit.

### BRIEF DESCRIPTION OF THE DRAWINGS

Referring to the exemplary drawings wherein like elements are numbered alike in the several Figures:

FIG. 1 is a cross sectional view of an exemplary silicon-on-insulator (SOI) field effect transistor (FET) suitable for use in accordance with an embodiment of the invention; and

FIGS. 2 through 4 illustrate a method and structure for reducing SOI floating body effects without junction leakage, in accordance with an embodiment of the invention.

### DETAILED DESCRIPTION

Disclosed herein is a method and structure for reducing silicon-on-insulator (SOI) floating body effects without junction leakage. Briefly stated, the SOI device is subjected to an angled implant of an amorphizing species such as Xe or Sb so as to introduce source side implant defects at a source p/n junction region of the transistor. Thereby, excess body charge due to floating body effects may be discharged through the grounded (in an NFET) source terminal. Due to the asymmetric angled implant, the presence of amorphizing species in the drain side of the device is completely localized within the drain diffusion so as not reduce the drain diode barrier height and increase thermal power dissipation and reduce switching speed of the device.

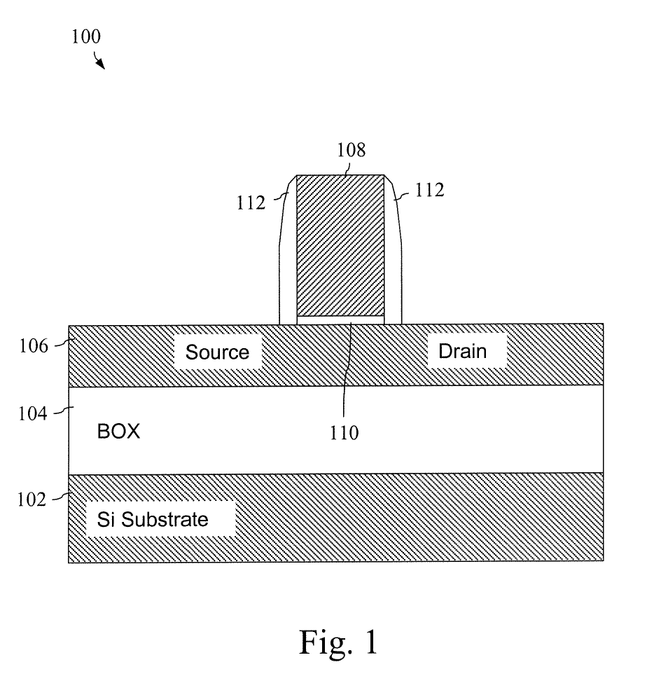

Referring initially to FIG. 1, there is shown a cross sectional view of an SOI device 100 suitable for use in accordance with an embodiment of the invention. The SOI device 100 includes a bulk substrate 102 (e.g., silicon), a buried insulation layer (BOX) 104 formed over the bulk substrate 102, and a crystalline silicon-on-insulator (SOI) layer 106 formed over the BOX layer 104. As further illustrated in FIG. 1, a gate electrode 108 (e.g., polysilicon) is formed over the SOI layer 106, with a gate insulating layer 110 therebetween, as will be recognized by one skilled in the art. A source region is subsequently formed on one side of the gate electrode 108 and a drain region on the opposite side of the gate electrode 108. In addition, a first set of sidewall spacers 112 (e.g., nitride) is formed adjacent side surfaces of the gate electrode 108 to facilitate source and drain diffusion implantation.

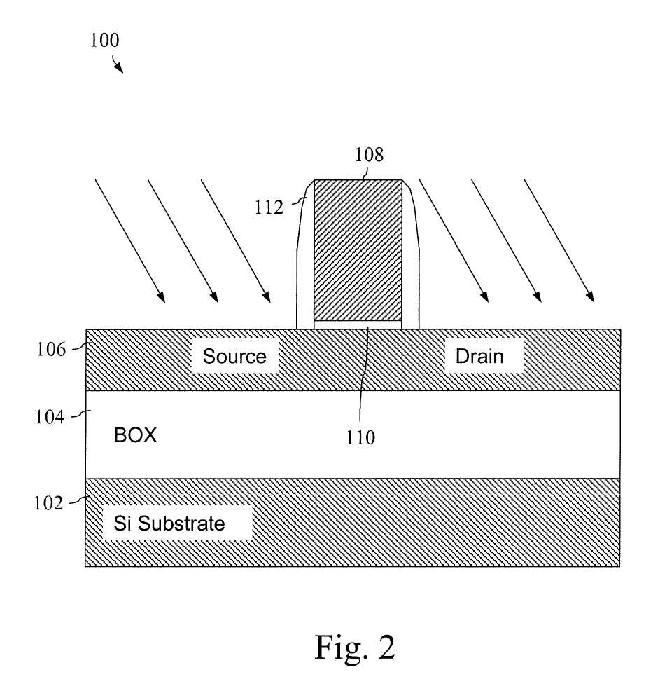

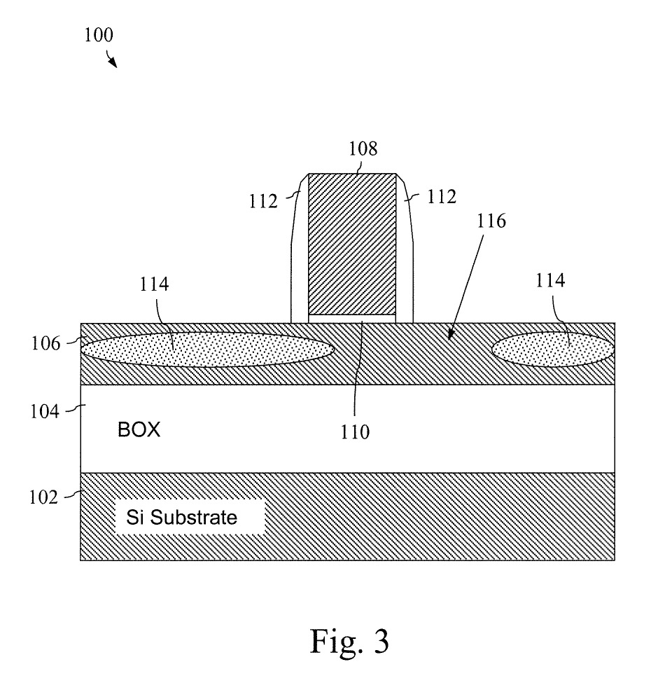

As shown in FIG. 2, the SOI device 100 is subjected to an angled implant of an amorphizing species such as Xe or Sb, for example, as indicated by the arrows. The implant, carried out at an angle of about 10 to about 45 degrees with respect to a normal axis of the substrate, results in an asymmetric implant structure with respect to the source and drain regions of the device. As more specifically shown in FIG. 3, implant regions 114 are formed within the SOI layer. However, whereas the implant region 114 on the source side of the device is shown extending beneath the gate electrode of the FET (i.e., across a subsequently formed source-to-body diode barrier), the implant region 114 of the corresponding drain side of the device does not, as indicated by arrow 116.

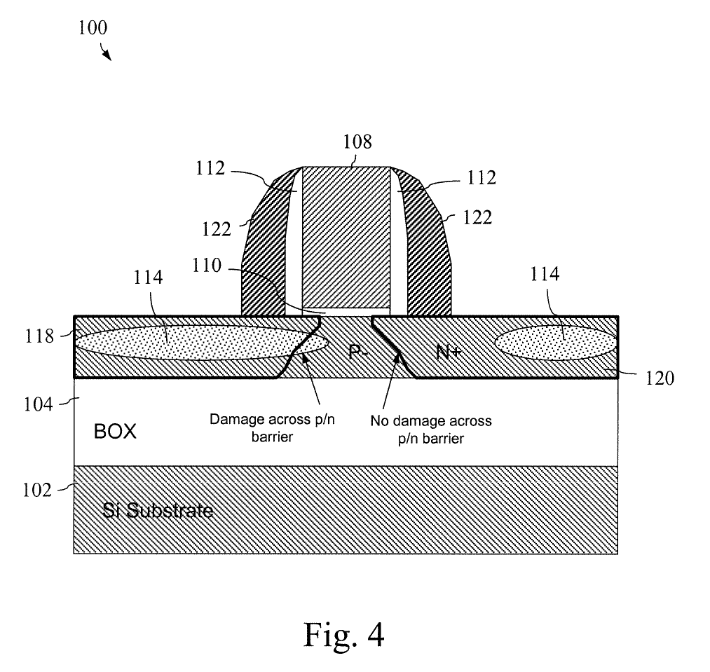

Finally, as shown in FIG. 4, the SOI device 100 is provided with source diffusion (and extension) regions 118 and drain diffusion (and extension) regions 120. As will thus be seen, for the exemplary n-type device 100, the implanted defects of region 114 on the source side are present across the source p/n junction. However the implanted defects of region 114 on the drain side are localized entirely within the drain region, and do not affect the drain p/n junction.

Thus, in an off state, the excess body charge of the SOI device 100 may be discharged via the damaged amorphized region 114 on the source side of the device, while the damaged region 114 on the drain side does not reduce the p/n diode barrier and contribute to junction leakage. Conversely, during an on state of the device 100, the hole injection from body to source is improved through the presence of defects that bridge across the source side p/n diode barrier. Through the use of the angled implant as thus described, the device need not be subjected to an extra lithography step in order to prevent introduction of the amorphizing, fault-generating species across the drain side p/n barrier.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of reducing silicon-on-insulator (SOI) floating body effects in a semiconductor device, the method comprising:
forming a buried insulator layer over a substrate material;
forming a crystalline SOI layer over the buried insulator layer;
forming a gate conductor over the SOI layer; and
performing an angled implant of the semiconductor device so as to introduce an amorphizing species into the SOI layer in an asymmetric manner with respect to source and drain regions of the device;
wherein the amorphizing species introduced into the source region of the device bridges across a source-to-body diode barrier, and wherein the amorphizing species introduced into the drain region of the device are localized entirely therein.

2. The method of claim 1, wherein the amorphizing species comprises xenon (Xe).

3. The method of claim 1, wherein the amorphizing species comprises antimony (Sb).

4. The method of claim 1, wherein the implant is performed at an angle of about 10 to about 45 degrees with respect to a normal axis of the substrate.

5. The method of claim 1, wherein the semiconductor device comprises an n-type field effect transistor (NFET).

6. The method of claim 1, further comprising forming source and drain diffusion and extension regions.

7. A silicon-on-insulator (SOI) transistor device, comprising:
a buried insulator layer formed over a substrate material;
a crystalline SOI layer over the buried insulator layer;
a gate conductor formed over the SOI layer; and
an amorphizing species distributed within the SOI layer in an asymmetric manner with respect to source and drain regions of the device;
wherein the amorphizing species introduced into the source region of the device bridges across a source-to-body diode barrier, and wherein the amorphizing species distributed within the drain region of the device are localized entirely therein.

8. The SOI transistor device of claim 7, wherein the amorphizing species comprises xenon (Xe).

9. The SOI transistor device of claim 7, wherein the amorphizing species comprises antimony (Sb).

10. The SOI transistor device of claim 7, further comprising source and drain diffusion and extension regions.
